(19) United States
(12) Patent Application Publication
(10) Pub. No.: US 2010/0237914 A1
(43) Pub. Date: Sep. 23, 2010

(54) CLOCK DISTRIBUTION DEVICE AND CLOCK DISTRIBUTION METHOD

(76) Inventor: TOSHIHIRO KATOH, Tokyo (JP)

Correspondence Address: Mr. Jackson Chen, 6535 N. STATE HWY 161, IRVING, TX, 75039, US

(21) Appl. No.: 12/716,345

(22) Filed: Mar. 3, 2010

(30) Foreign Application Priority Data
Mar. 23, 2009 (JP) 69411/2009

(51) Int. Cl. H03L 7/06

(52) U.S. Cl. 327/149

(57) ABSTRACT

A clock distribution device to an exemplary aspect of the invention includes: a first clock output unit outputting a first clock synchronized to a reference clock; a second clock output unit outputting a second clock synchronized to the reference clock; a first clock distribution unit including a first branch point, branching the first clock at the first branch point and outputting a third clock; a second clock distribution unit including a second branch point, branching the second clock at the second branch point and outputting a fourth clock; and a phase difference detecting unit detecting a first phase difference between a phase of the third clock and a phase of the fourth clock, and the second clock output unit controls a second phase difference between a phase of the first clock and a phase of the second clock so that the first phase difference is reduced.

### INCORPORATION BY REFERENCE

This application is based upon and claims the benefit of priority from Japanese Patent Application No. 2009-069411, filed on Mar. 23, 2009, the disclosure of which is incorporated herein in its entirety by reference.

### TECHNICAL FIELD

The present invention relates to a clock distribution device and a clock distribution method, and particularly relates to a clock distribution device and a clock distribution method by which it is possible to reduce the clock skew between clocks belonging to different clock systems each other.

### BACKGROUND ART

A logic circuit often carries out a synchronous operation by use of a clock. Since the clock is distributed to many places in the logic circuit, phase difference between the distributed clocks, that is, “clock skew” may be caused. In case of a synchronous circuit which uses the clock, it is desirable to make the clock skew as small as possible. As the clock speed becomes high, an influence which the clock skew causes becomes serious. Therefore, the higher the clock speed by which a circuit works is, the more necessary to reduce the clock skew is.

Moreover, there is a problem that as the physical scale of the circuit becomes large, the clock skew becomes large. For example, as the die size of a semiconductor integrated circuit becomes large, difference between wiring length of the longest clock line and wiring length of the shortest one becomes large, with regard to length of the clock line from a clock source to a clock destination. Therefore, variation in the delay time from the clock source to the clock destination becomes large and consequently, the clock skew becomes large.

The circuit which uses high speed clock often uses a PLL (Phase Locked Loop) in order to multiply low speed clock to high speed clock. The high speed clock is distributed to many places inside the circuit, and is used for transferring synchronous data or the like. With regard to a method for reducing the clock skew in case of using a PLL, there is a method to make a circuit area, to which the clock distributed from one PLL is distributed, small. The method premises that the circuit has a plurality of PLLs inside. Even if the method would be used, there may exist a path, which is required to be synchronized, between the circuits each of which uses the clock distributed from different PLLs. Also in the case, there is a problem that the synchronous operation cannot be carried out normally.

Japanese Patent Application Laid-Open No. 2007-336003 (hereinafter, referred to as patent document 1) and Japanese Patent Application Laid-Open No. 2008-219216 (hereinafter, referred to as patent document 2) disclose related arts on reduction of the clock skew in case that a plurality of PLLs are used. According to a clock distribution circuit disclosed in the patent document 1, each of the plural PLLs composes a “clock tree.” The clock tree is a clock line which takes a shape like a tree as a whole through repeated branching of the clock line. The clock at the predetermined branch point of each clock tree is fed back to the corresponding PLL and the phase of the clock is aligned with the phase of the reference clock which is inputted to the PLL. The reference clock is inputted to each of the PLLs in common. Accordingly, the phase of the clock at the branch point of each clock tree is aligned. That is, the clock skew between the clock trees is reduced.

According to a clock supplying device disclosed in the patent document 2, a variable delay circuit is controlled so that the phase of the clock belonging to one clock system among two clock systems, and the phase of the clock belonging to the other clock system may be aligned each other. Accordingly, the clock skew between the clocks belonging the different clock systems each other is reduced.

### SUMMARY

An exemplary object of the present invention is to provide a clock distribution device and a clock distribution method by which clock skew between a plurality of clock systems can be reduced.

A clock distribution device to an exemplary aspect of the invention includes: a first clock output unit outputting a first clock synchronized to a reference clock; a second clock output unit outputting a second clock synchronized to the reference clock; a first clock distribution unit including a first branch point, branching the first clock at the first branch point and outputting a third clock; a second clock distribution unit including a second branch point, branching the second clock at the second branch point and outputting a fourth clock; and a phase difference detecting unit detecting a first phase difference between a phase of the third clock and a phase of the fourth clock, and the second clock output unit controls a second phase difference between a phase of the first clock and a phase of the second clock so that the first phase difference is reduced.

A clock distribution method to another exemplary aspect of the invention includes: detecting a first phase difference between a phase of a third clock branched from a first branch point of a first clock distribution unit and a phase of a fourth clock branched from a second branch point of a second clock distribution unit; and controlling a second phase difference between a phase of the first clock and a phase of the second clock so that the first phase difference is reduced.

### BRIEF DESCRIPTION OF THE DRAWINGS

Exemplary features and advantages of the present invention will become apparent from the following detailed description when taken with the accompanying drawings in which:

FIG. 1 is a block diagram showing a configuration of a clock distribution device according to a first exemplary embodiment of the present invention;

FIG. 2 is a block diagram showing an example of an internal configuration of a second clock output unit of the clock distribution device according to the first exemplary embodiment of the present invention;

FIG. 3 is a block diagram showing a configuration of a clock distribution circuit according to a second exemplary embodiment of the present invention;

FIG. 4 is a circuit diagram showing a circuit configuration around an end of a clock distribution circuit according to a third exemplary embodiment of the present invention;

FIG. 5 is a circuit diagram showing an exemplary configuration of a transfer gate;

FIG. 6 is a circuit diagram showing a circuit configuration around an end of a clock distribution circuit according to a fourth exemplary embodiment of the present invention;

FIG. 7 is a circuit diagram showing a circuit configuration of a phase difference detecting unit of a clock distribution circuit according to a fifth exemplary embodiment of the present invention;

FIG. 8 is a table showing an operation of a delay circuit of the clock distribution circuit corresponding to the combination of outputs of the phase difference detecting unit, of the clock distribution circuit according to the fifth exemplary embodiment of the present invention;

FIG. 9 is a circuit diagram showing a circuit configuration of a phase difference detecting unit of a clock distribution circuit according to a sixth exemplary embodiment of the present invention;

FIG. 10 is a table showing an operation of a delay circuit of the clock distribution circuit corresponding to the combination of outputs of the phase difference detecting unit, of the clock distribution circuit according to the sixth exemplary embodiment of the present invention; and

FIG. 11 is a circuit diagram showing a configuration of a clock distribution circuit disclosed in the patent document 1.

### EXEMPLARY EMBODIMENT

Exemplary embodiments of the present invention will now be described in detail in accordance with the accompanying drawings.

### 1. First Exemplary Embodiment

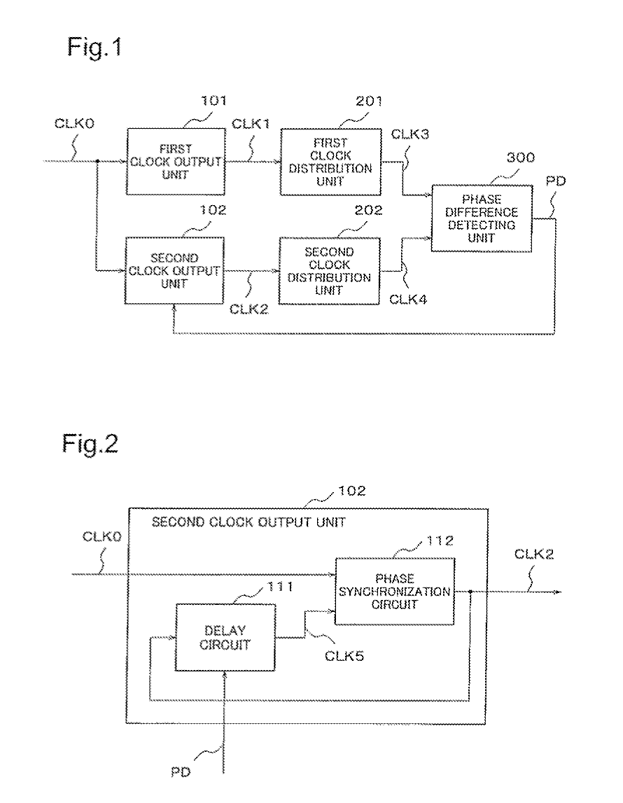

A clock distribution device will be described in detail in the following with reference to a drawing according to the first exemplary embodiment of the present invention. FIG. 1 is a block diagram showing a configuration of the clock distribution device according to the first exemplary embodiment of the present invention. The clock distribution device according to the first exemplary embodiment of the present invention includes a first clock output unit 101, a second clock output unit 102, a first clock distribution unit 201, a second clock distribution unit 202 and a phase difference detecting unit 300.

The first clock output unit 101 inputs a reference clock (hereinafter, referred to as CLK0) and outputs a first clock (hereinafter, referred to as CLK1) which is synchronized to CLK0. In the specification of the present invention, “synchronization” means that the clocks belonging to two different clock systems each other have a predetermined phase relation each other. Moreover, in case that one clock has the jitter which varies in the predetermined range from the phase of the other clock, it is assumed that the one clock is also synchronized to the other clock. In short, as long as one clock has one to one relation with the other clock from local point of view, it is assumed that the clocks belonging to the two different clock systems each other are synchronized each other. Incidentally, the jitter included in the clock is called the “clock jitter” hereinafter.

The second clock output unit 102 inputs CLK0 and outputs a second clock (hereinafter, referred to as CLK2) which is synchronized to CLK0. At this point of time, the second clock output unit 102 adjusts the phase of CLK0 on the basis of a phase difference signal PD which will be mentioned later, and outputs the adjusted CLK0 as CLK2.

The first clock distribution unit 201 branches CLK1 once or a plurality of times and supplies the branched CLK1 as a third clock (hereinafter, referred to as CLK3) to a circuit which works in synchronization to CLK1. The second clock distribution unit 202 branches CLK2 once or a plurality of times and supplies the branched CLK2 as a fourth clock (hereinafter, referred to as CLK4) to a circuit which works in synchronization to CLK2. The first clock distribution unit 201 and the second clock distribution unit 202 are composed of signal wirings which takes a shape like the clock tree mentioned above as a whole.

The phase difference detecting unit 300 detects a phase difference (hereinafter, referred to as first phase difference) between CLK3 and CLK4 and outputs a phase difference signal (hereinafter, referred to as PD) which indicates the first phase difference.

As mentioned above, CLK1 is transferred through the first distribution unit 201 and outputted by the first clock distribution unit 201 as CLK3. CLK2 is transferred through the second distribution unit 202 and outputted by the second clock distribution unit 202 as CLK4. Since CLK3 is the transferred CLK1 through the first clock distribution unit 201, the phase of CLK3 is delayed in comparison with the phase of CLK1. Similarly, since CLK4 is the transferred CLK2 through the second clock distribution unit 202, the phase of CLK 4 is delayed in comparison with the phase of CLK2. Moreover, since CLK3 and CLK4 are the transferred CLK1 and CLK2 through the different clock distribution units, the phase difference (first phase difference) between CLK3 and CLK4 may be large. According to the clock distribution device of the exemplary embodiment of the present invention, the phase of CLK2 is adjusted so that the first phase difference may be made close to zero.

An operation of the second clock output unit 102 for adjusting the phase of CLK2 will be described in the following. The second clock output unit 102 adjusts the phase of CLK0 on the basis of the first phase difference indicated by PD and outputs the adjusted CLK0 as CLK2. That is, the second clock output unit 102 sets a phase difference (hereinafter, referred to as second phase difference) between CLK2 and CLK0 on the basis of the first phase difference, and outputs CLK2 which has the phase difference from the phase of CLK0.

Then, through controlling the second phase difference so as to make the first phase difference small and so as to make the first phase difference null ideally, the second clock output unit 102 adjusts the phase of CLK 2. A specific example of the method for adjusting the phase of CLK2 is described in the following. In case that the phase of CLK4 is advanced in comparison with the phase of CLK3, the phase of CLK2 made delayed. On the other hand, in case that the phase of CLK4 is delayed in comparison with the phase of CLK3 conversely, the phase of CLK2 is made advanced. Accordingly, the phase difference (first phase difference) between CLK3 and CLK4 approaches to zero.

As understood clear from the above mentioned description, it is not ensured that the to clock skew becomes null perfectly. However, the first phase difference approaches to zero for certain. That is, the clock skew between CLK3 and CLK4 is reduced for certain.

Incidentally, it is desirable that step size (hereinafter, referred to as phase shift step size), which means an amount of phase shift activated by the second clock output unit 102 for adjusting the phase of CLK2, is smaller than maximum acceptable value of the clock skew (hereinafter, referred to as acceptable skew value) between CLK3 and CLK4. That is, it is desirable that the phase shift step size is smaller than the maximum acceptable value of the first phase difference. The acceptable skew value means the largest clock skew value which makes the circuit work normally and the acceptable clock skew value has a positive acceptable skew value and a negative acceptable skew value. The absolute value of the positive acceptable skew value is not always equal to one of the negative acceptable skew value. Therefore, the phase shift step size may be set to an adequately small value so that the circuit, which uses CLK3 and CLK4, can work normally, that is, the clock skew may be set not smaller than the negative acceptable skew value and not larger than the positive acceptable skew value.

Incidentally, while the phase of CLK2 is adjusted through changing the delay time in a certain step size in the above mentioned method, the first phase difference may be measured actually, and then, the second phase difference may be set on the basis of the measurement. In other words, the phase of CLK2 may be adjusted not by repetition of the control for advancing the phase and the control for delaying the phase but by setting the second phase difference to a certain value which is determined uniquely by the first phase difference.

There are two kinds of methods for setting the second phase difference. One method is to measure the first phase difference in the digital way, and to set the second phase difference in the digital way on the basis of the measurement. The other method is to measure the first phase difference in the analog way. For example, the voltage based on the phase difference is generated, and the phase is set in the analog way on the basis of the generated voltage.

FIG. 2 is a block diagram showing an example of an internal configuration of the second clock output unit 102. The second clock output unit 102 includes a delay circuit 111 and a phase synchronization circuit 112. The delay circuit 111 makes CLK2 delayed on the basis of PD, and outputs the delayed CLK2 to the phase synchronization circuit 112 as a fifth clock (hereinafter, referred to as CLK5).

The phase synchronization circuit 112 makes CLK0 delayed so as to make the phase difference between CLK0 and CLK5, which are the two different clock systems each other, null and outputs the delayed CLK0 as CLK2. The phase synchronization circuit 112, which includes an oscillator, may control the oscillator so as to make the phase difference between CLK0 and CLK5 null, as a normal PLL does.

As mentioned above, the clock distribution device according to the first exemplary embodiment of the present invention adjusts the phase of the clock, which is inputted to the clock distribution unit, on the basis of the phase difference between two clocks which belong to two different clock systems and which are outputted via each of the clock distribution units. Therefore, the clock distribution device has an effect that it is possible to reduce the phase difference of two clocks which belong to two different clock systems and which are outputted via each of the clock distribution units.

### 2. Second Exemplary Embodiment

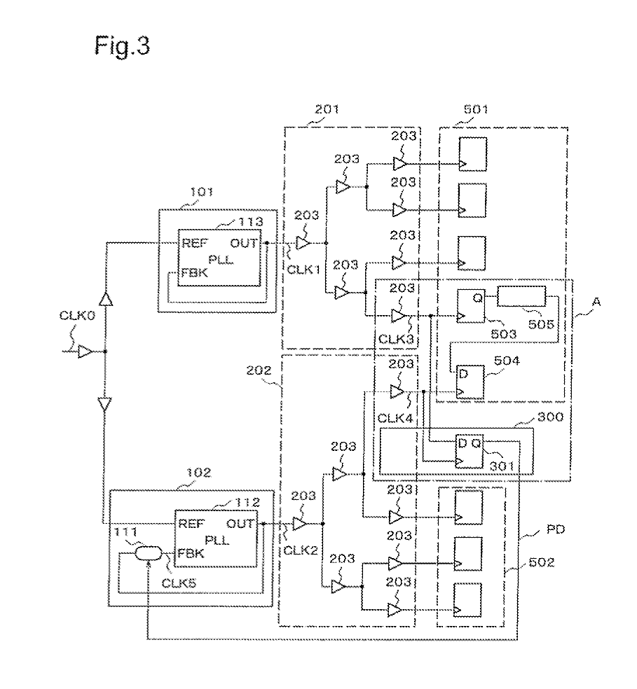

The second exemplary embodiment of the present invention will be described in detail in the following with reference to a drawing. FIG. 3 is a circuit diagram showing a configuration of a clock distribution circuit according to the second exemplary embodiment of the present invention. The second exemplary embodiment shows an example of a specific circuit configuration which is the internal configuration of the clock distribution device of the first exemplary embodiment of the present invention.

The clock distribution circuit according to the second exemplary embodiment of the present invention includes the first clock output unit 101, the second clock output unit 102, the first clock distribution unit 201, the second clock distribution unit 202, the phase difference detecting unit 300, an operating circuit 501 and an operating circuit 502.

The first clock output unit 101 has a PLL 113. The second clock output unit 102 includes a PLL 112 and the delay circuit 111.

Incidentally, a component, to which the same reference number is attached as the one attached to component of the clock distribution device of the first exemplary embodiment of the present invention as shown in FIG. 1, of the clock distribution circuit shown in FIG. 3 has the same function as the component, to which the reference number is attached, of the first exemplary embodiment of the present invention. Description on the components attached with the same reference number is omitted.

Each of the first clock distribution unit 201 and the second clock distribution unit 202 constitute a clock tree. The first clock distribution unit 201 and the second clock distribution unit 202 have clock drivers 203. The clock driver 203 is used in order to improve driving ability for the clock signal. The clock driver 203 does not have any logical influence on signal. The phase difference detecting unit 300 includes a D-type flip flop (hereinafter, just referred to as F/F) 301.

A circuit configuration of the clock distribution circuit will be described in the following according to the exemplary embodiment of the present invention. The operating circuit 501 includes F/F 503, F/F 504 and a logic circuit 505. The data output of F/F 503 is inputted to the logic circuit 505. The output of the logic circuit 505 is connected to the data input of F/F 504.

CLK1, which is the output of the first clock output unit 101, is inputted to the clock tree and CLK1, which is transferred through the clock tree, is denoted by CLK3 at the end of the clock tree. CLK 3 is inputted to the clock input of F/F 503 and the data input of F/F 301 of the phase difference detecting unit 300. CLK2, which is the output of the second clock output unit 102, is inputted to the clock tree and CLK2, which is transferred through the clock tree, is denoted by CLK4 at the end of the clock tree. CLK 4 is inputted to the clock input of F/F 504 and the clock input of F/F 301 of the phase difference detecting unit 300.

Next, an operation of the clock distribution circuit according to the exemplary embodiment of the present invention will be described. CLK1 is distributed along the clock tree of the first clock distribution unit 201 to become CLK3 at the end of the clock tree, and CLK 3 reaches the operating circuit 501. Similarly, CLK2 is distributed along the clock tree of the second clock distribution unit 202 to become CLK4 at the end of the clock tree, and CLK 4 reaches the operating circuit 502.

The first clock output unit 101 compares the phase of CLK0, which is supplied from the outside, with the phase of CLK1 fed back directly from the output of the first clock output unit 101. Then, the first clock output unit 101 makes CLK1 synchronized to CLK0. As mentioned above, the clock at the end of the first clock distribution 201 is not fed back to the first clock output unit 101. Accordingly, the clock jitter included in the clock which is fed back to the first clock output unit 101 is reduced substantially, and the clock skew is also reduced.

The second clock output unit 102 has the same function and the same effect as the first clock output unit 101 has. The second clock output unit 102 compares the phase of CLK0, which is supplied from the outside, with the phase of CLK2 fed back directly from the output of the second clock output unit 102, and then the first clock output unit 101 makes CLK2 synchronized to CLK0. Accordingly, the clock jitter included in the clock which is fed back to the second clock output unit 102 is reduced substantially, and the clock skew is also reduced.

Since F/F 503 works in synchronization to the rising edge of CLK3, the output of the logic circuit 505 also changes in synchronization to the rising edge of CLK3. F/F 504 stores the output of the logic circuit 505, which changes in synchronization to the rising edge of CLK3, in synchronization to the rising edge of CLK4.

In an initial state in which the clock distribution circuit does not carry out the phase control for CLK2, the phases of CLK3 and CLK4 may not be identical each other. The reason is that transmission delay time of the clock through the first clock distribution unit 201 and one through the second clock distribution unit 202 are not always identical each other. Taking this point into consideration, the clock distribution circuit according to the exemplary embodiment of the present invention changes the phase of CLK2 so as to make the phases of CLK3 and CLK4 identical each other.

F/F 301 which is a component of the phase difference detecting unit 300 samples CLK3 in synchronization to the rising edge of CLK4. Therefore, in case that the rising edge of CLK3 is delayed in comparison with the rising edge of CLK4, the output of F/F 301 is zero. On the other hand, in case that the rising edge of CLK3 is advanced in comparison with the rising edge of CLK4, the output of F/F 301 is one. In other words, in case that the phase of CLK3 is delayed in comparison with that of CLK4, the output of F/F 301 is zero, and, in case that the phase of CLK3 is advanced in comparison with that of CLK4, the output of F/F 301 is one. Incidentally, the output of F/F 301 is PD.

In case that PD is equal to zero, that is, the phase of CLK3 is delayed in comparison with the phase of CLK4, it is possible to make the phase of CLK4 close to the phase of CLK3 through delaying the phase of CLK2. Therefore, in case that PD is equal to zero, an amount of delay time of the delay circuit 111 is made short and consequently, the phase of CLK2 is made delayed.

On the other hand, in case that PD is equal to one, that is, in case that the phase of CLK3 is advanced in comparison with the phase of CLK4, it is possible to make the phase of CLK4 close to the phase of CLK3 through advancing the phase of CLK2. Therefore, in case that PD is equal to one, an amount of delay time of the delay circuit 111 is made long and consequently, the phase of CLK2 is made advanced.

Through repeating the delay time adjustment mentioned above, the phases of CLK3 and CLK4 are made close each other. That is, the clock skew between CLK3 and CLK4 is reduced.

As mentioned above, the clock distribution circuit according to the exemplary embodiment of the present invention adjusts the phase of the clock, which is inputted to the clock distribution unit, on the basis of the phase difference of the clocks at the end of two clock distribution units. Therefore, the clock distribution circuit has an effect that it is possible to reduce the phase difference between two clocks at the end of the clock distribution units.

Moreover, the clock at the end of clock distribution unit is not fed back to the input of the clock output unit. Therefore, the clock distribution circuit has an effect that it is possible to reduce substantially the clock jitter included in the clock which is fed back, and to reduce also the clock skew.

### 3. Third Exemplary Embodiment

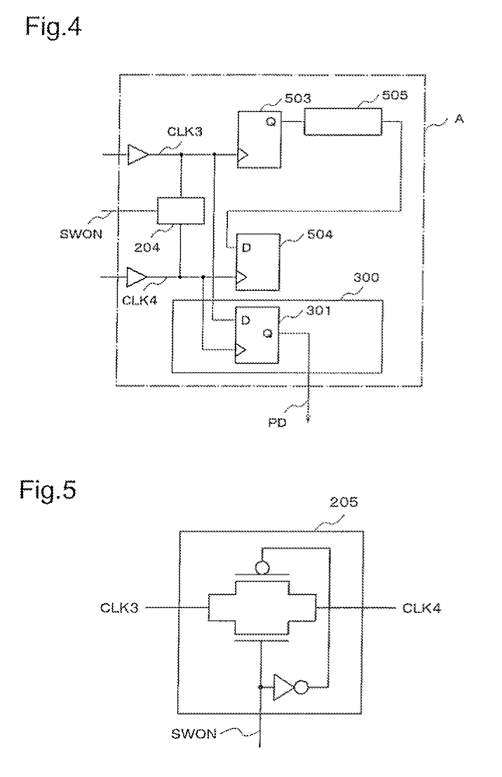

The third exemplary embodiment of the present invention will be described in the following with reference to FIG. 4 and FIG. 5. The clock distribution circuit according to the third exemplary embodiment has a switch circuit for short-circuiting the clocks belonging to the two different clock systems each other in addition to the clock distribution circuit of the second exemplary embodiment, in order to make the skew smaller. FIG. 4 is a circuit diagram showing a circuit configuration around an end of the clock distribution unit according to the third exemplary embodiment. The end portion of the clock distribution unit is indicated by “A” in FIG. 3. Other components of the clock distribution circuit of the exemplary embodiment of the present invention are the same as those of the clock distribution circuit of the second exemplary embodiment.

As shown in FIG. 4, the clock distribution circuit has a switch circuit 204 arranged between clock lines of CLK3 and CLK4. The switch circuit 204 is controlled by a switch control signal SWON. A transfer gate 205 is shown in FIG. 5 as a specific example of the switch circuit 204. In case that SWON is equal to one, the transfer gate 205 makes the clock line of CLK3 and the clock line of CLK4 short-circuited together. On the other hand, in case that SWON is equal to zero, the transfer gate 205 makes the clock line of CLK3 and the clock line of CLK4 disconnected together.

In an initial state in which the clock distribution circuit according to the exemplary embodiment of the present invention does not start the control operation, the phases of CLK3 and CLK4, which belong to the two different clock systems each other, may not be identical each other. Therefore, SWON is set to zero in the initial state to prevent the clock line of CLK3 and the clock line of CLK4 from being short-circuited together. After the phase adjustment for CLK3 and CLK4 has been completed by the control operation described in the second exemplary embodiment of the present invention, SWON is set to one to make the clock line of CLK3 and the clock line of CLK4 short-circuited together. According to the clock distribution circuit of the third exemplary embodiment, the phase difference (first phase difference) between CLK3 and CLK4 also may not be controlled to be null precisely, as described in the first exemplary embodiment of the present invention. However, the first phase difference is reduced for certain. Incidentally, “completion of the phase adjustment” means to be in a state in which the first phase difference is reduced sufficiently by the function of the phase adjustment for CLK2.

It is possible to judge that the phase adjustment has just been completed, for example when the direction of the phase adjustment for CLK2 is changed into the reverse direction. The direction of the phase adjustment for CLK2 is either the direction in which the phase of CLK2 is advanced or the direction in which the phase is delayed. Moreover, it is also possible to judge that the operation for reducing the first phase difference has just been completed when a predetermined time has passed after start of the phase adjustment of CLK2.

In a state in which the phase adjustment for CLK3 and CLK4 has been completed, the clock distribution circuit makes the clock line of CLK3 and the clock line of CLK4 short-circuited compulsorily. Accordingly, the phase difference between CLK3 and CLK4 are reduced further.

Since, as mentioned above, the switch circuit 204 makes both the clock line of CLK3 and the clock line of CLK4 compulsorily short-circuited together even if in a state in which the phase difference between CLK3 and CLK4 is left, it is desirable that ON resistance of the switch circuit 204 is as small as possible.

CLK3 and CLK4 are supplied to F/F 503, F/F 504 and the logic circuit 505 or the like, that is, the operating circuits 501 and 502. Since the phases of CLK3 and CLK4 are compulsorily made identical each other, the operating circuits 501 and 502 can carry out the synchronous operation for certain.

As mentioned above, the clock distribution circuit according to the third exemplary embodiment of the present invention makes the clocks, which belong to the two different clock systems each other, compulsorily short-circuited together after reducing the clock skew between the clocks. Therefore, the clock distribution circuit has an effect that it is possible to reduce the clock skew further in addition to reduction of the clock skew by the phase adjustment of the clock. Moreover, the clock distribution circuit has another effect that the clocks belonging to the two different clock systems each other are not short-circuited together while the clock skew between the clocks is left.

### 4. Fourth Exemplary Embodiment

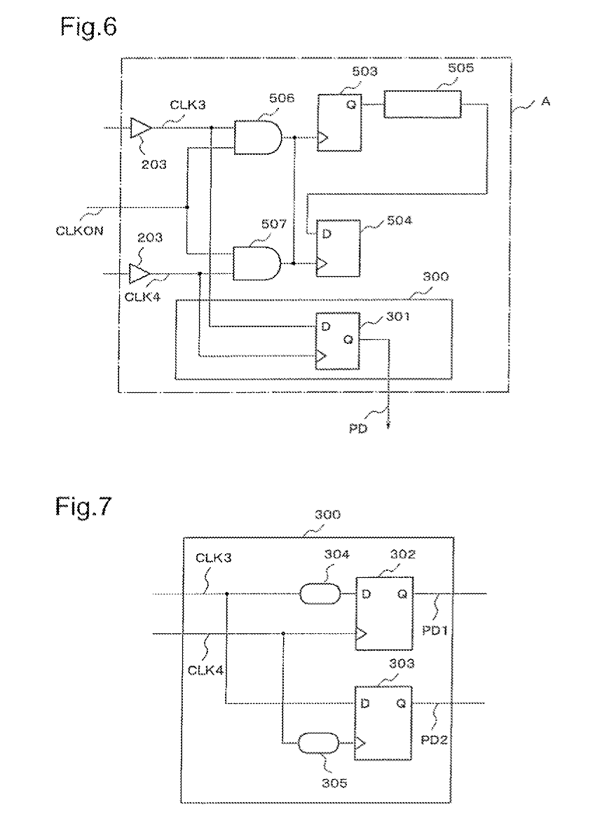

The fourth exemplary embodiment of the present invention will be described in the following with reference to FIG. 6. The clock distribution circuit according to the fourth exemplary embodiment also has a short-circuit unit which makes the clocks belonging to the two different clock systems short-circuited together like the third exemplary embodiment. Moreover, the clock distribution circuit according to the fourth exemplary embodiment has a clock stop circuit which stops supply of the clock just in front of the short-circuit unit. FIG. 6 is a circuit diagram showing a circuit configuration around an end of the clock distribution circuit according to the fourth exemplary embodiment. The end portion of the clock distribution unit is indicated by “A” in FIG. 3. Other components of the clock distribution circuit of the fourth exemplary embodiment are the same as those of the clock distribution circuit of the second exemplary embodiment.

In the clock distribution circuit of the fourth exemplary embodiment, AND gates 506 and 507 are added to the clock lines of CLK3 and CLK4 respectively. Then, supply of the clock to a circuit which follows AND gates 506 and 507, is controlled by a clock supply permission signal CLKON. The outputs of AND gates 506 and 507 are short-circuited together.

In case that CLKON is equal to zero, each output of AND gates 506 and 507 is set to zero. On the other hand, in case that CLKON is equal to one, AND gates 506 and 507 output CLK3 and CLK4 respectively. Then, CLK3 and CLK4 are short-circuited together and are supplied to F/F 503, F/F 504, the logic circuit 505 or the like, that is, the operating circuits 501 and 502. Since the phases of CLK3 and CLK4 are compulsorily made identical each other, the operating circuits 501 and 502 can carry out the synchronous operation for certain.

In an initial state in which the clock distribution circuit according to the exemplary embodiment of the present invention does not start the control operation, the phases of CLK 3 and CLK 4, which belong to the two different clock systems each other, may not be identical each other. Therefore, in the initial state, CLKON is set to zero to control the outputs of AND gates 506 and 507 not to be short-circuited. Accordingly, in a state in which the clock skew between CLK3 and CLK4 is left, CLK3 and CLK4 are not short-circuited together. After the phase adjustment for CLK3 and CLK4 has been completed by the control operation described in the second exemplary embodiment, CLKON is set to one to make the clock line of CLK3 and the clock line of CLK4 short-circuited together. The meaning of the completion of the phase adjustment has been described in the third exemplary embodiment. The method for judging the completion of the phase adjustment has been also described in the third exemplary embodiment.

As mentioned above, the clock distribution circuit according to the fourth exemplary embodiment of the present invention makes the clocks, which belong to the two different clock systems each other, compulsorily short-circuited together after reducing the clock skew between the clocks. Therefore, the clock distribution circuit has an effect that it is possible to reduce the clock skew further in addition to reduction of the clock skew by the phase adjustment of the clock.

Moreover, supply of the clock to the short-circuit unit is stopped before the clock skew is reduced by the phase adjustment of the clock. Therefore, the clock distribution circuit has another effect that the clocks belonging to the two different clock systems are not short-circuited together while the clock skew between the clocks is left.

### 5. Fifth Exemplary Embodiment

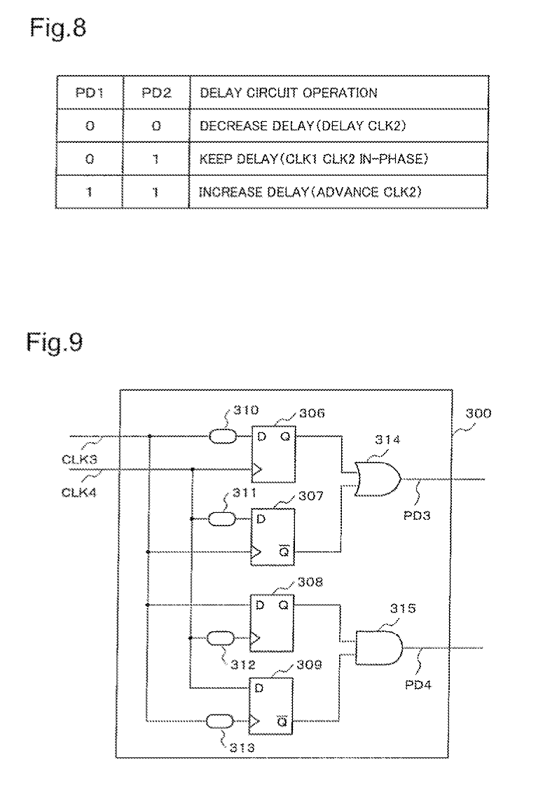

The fifth embodiment of the present invention will be described in the following with reference to FIG. 7 and FIG. 8. The clock distribution circuit of the fifth exemplary embodiment is the one added a function to detect whether the phases of the clocks belonging to the two different clock systems are identical each other to the difference detecting function of the phase difference detecting unit. FIG. 7 is a circuit diagram showing a circuit configuration of the phase difference detecting unit of the clock distribution circuit of the fifth exemplary embodiment. FIG. 8 is a table showing an operation of a delay circuit on the basis of combination of outputs of the phase difference detecting unit shown in FIG. 7.

As shown in FIG. 7, the phase difference detecting unit 300 according to the fifth exemplary embodiment includes F/F 302, F/F 303 and delay elements 304 and 305. CLK3 is delayed by the delay element 304, and the delayed CLK3 is inputted to the data input of F/F 302. CLK4 is inputted to the clock input of F/F 302 with no delay. Moreover, CLK3 is inputted to the data input of F/F 303 with no delay. CLK4 is delayed by the delay element 304, and the delayed CLK4 is inputted to the clock input of F/F 303. Incidentally, combination of outputs of F/F 302 and F/F 303 corresponds to the phase difference signal PD. Hereinafter, the outputs of F/F 302 and F/F 303 are denoted as PD1 and PD2 respectively.

Relation between the values of PD1 and PD2 and the control for the delay circuit is shown in FIG. 8. In case that the phase of CLK3 is delayed in comparison with the phase of CLK4, PD1 and PD2 are set to zero together. In this case, an amount of delay time of the delay circuit 111 is set short so as to delay the phase of CLK4, and consequently, the phase of CLK2 is delayed.

In case that the phase of CLK3 is advanced in comparison with the phase of CLK4, PD1 and PD2 are set to one together. In this case, an amount of delay time of the delay circuit 111 is set long so as to advance the phase of CLK4, and consequently, the phase of CLK2 is advanced.

Through repeating the operation for adjusting the amount of delay time, it is possible to make the phases of CLK3 and CLK4 close each other. That is, the clock skew between CLK3 and CLK4 is reduced. The function for reducing the clock skew by the phase adjustment for CLK2 is the same as that of the second exemplary embodiment.

The phase difference detecting unit 300 according to the fifth exemplary embodiment of the present invention has the function to detect whether the phases of CLK3 and CLK4 are identical each other. That is, since PD1 is set to zero and PD2 is set to one when the phases of CLK3 and CLK4 are identical each other, it is possible to detect that two phases are identical each other. In this case, the value of the delay time at the point of time is kept as the amount of the delay time of the delay circuit 111.

If the function for detecting whether the phases of CLK3 and CLK4 are identical each other is not installed, the operation for adjusting the clock phase would continue sequentially even when the phases are actually identical each other. Accordingly, the clock skew between CLK3 and CLK4 is caused. Furthermore, there is a phenomenon that relation between CLK3 and CLK4 on the advance or the delay of the phase may be reversed every time. In this case, not only existence of the skew but also shortage in the timing margin of the logic circuit are caused as a new problem.

However, the clock distribution circuit of the fifth exemplary embodiment stops adjusting the phase, in case that it is judged that the phases of CLK3 and CLK4 are identical each other. Therefore, the above-mentioned problem is not caused. In case that the phase difference between CLK3 and CLK4 emerges again, the clock distribution circuit according to the fifth exemplary embodiment of the present invention resumes the operation for adjusting the phase and controls the phase so that two phases may be identical each other.

As mentioned above, the phase detecting unit of the clock distribution circuit according to the fifth exemplary embodiment of the present invention has the function to detect whether the phases of clocks belonging to two different clock systems are identical each other. Therefore, it is possible to prevent the clock skew due to the continuous phase adjustment. Accordingly, the clock distribution circuit of the fifth exemplary embodiment has an effect that it is possible to reduce clock skew more than the clock distribution circuit of the second and the third exemplary embodiments can reduce.

Moreover, there is no phenomenon that relation between CLK3 and CLK4 on the advance or the delay of the phase may be reversed every time. Therefore, the clock distribution circuit also has an effect that it is possible to prevent the problem of shortage in the timing margin of the logic circuit.

### 6. Sixth Exemplary Embodiment

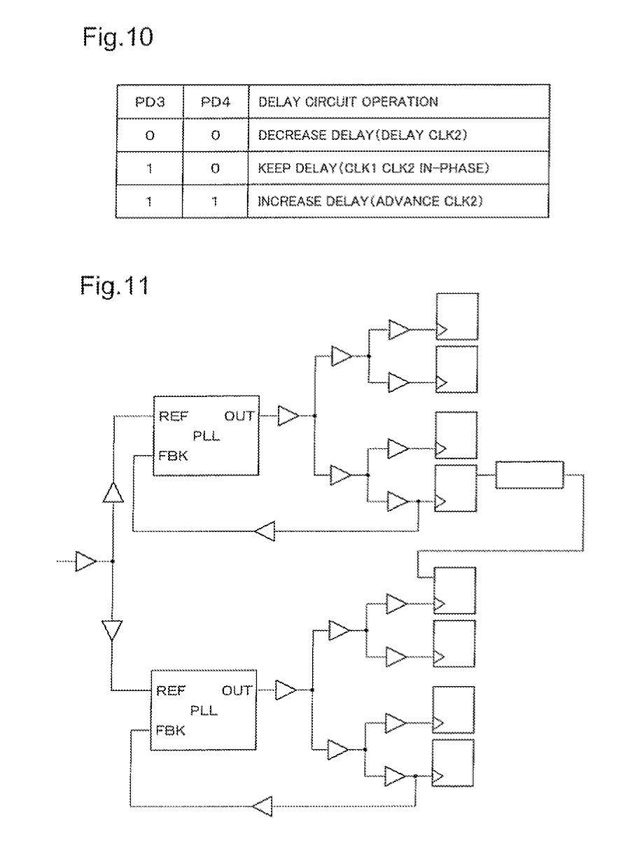

The sixth exemplary embodiment of the present invention will be described in the following with reference to FIG. 9 and FIG. 10. The clock distribution circuit of the sixth exemplary embodiment is the one added a function to detect whether the phases of the clocks belonging to the two different clock systems are identical each other to the difference detecting function of the phase difference detecting unit, like the clock distribution circuit of the fifth exemplary embodiment. FIG. 9 is a circuit diagram showing a circuit configuration of the phase difference detecting unit of the clock distribution circuit of the sixth exemplary embodiment. FIG. 10 is a table showing an operation of a delay circuit on the basis of combination of outputs of the phase difference detecting unit shown in FIG. 9.

As shown in FIG. 9, the phase difference detecting unit 300 according to the sixth exemplary embodiment includes F/Fs 306, 307, 308 and 309, delay elements 310, 311, 312 and 313, OR gate 314 and AND gate 315.

CLK3 is delayed by the delay element 310, and the delayed CLK3 is inputted to the data input of F/F 306. CLK4 is inputted to the clock input of F/F 306 with no delay. CLK4 is delayed by the delay element 311, and the delayed CLK4 is inputted to the data input of F/F 307. CLK3 is inputted to the clock input of F/F 307 with no delay. CLK3 is inputted to the data input of F/F 308 with no delay. CLK4 is delayed by the delay element 312, and the delayed CLK 4 is inputted to the clock input of F/F 308. CLK4 is inputted to the data input of F/F 309 with no delay. CLK3 is delayed by the delay element 313, and the delayed CLK 3 is inputted to the clock input of F/F 309.

Then, the output of F/F 306 and the reversed output of F/F 307 are inputted to the OR gate 314, and the output of F/F 308 and the reversed output of F/F 309 are inputted to the AND gate 315. Combination of the output of the OR gate 314 and the AND gate 315 corresponds to the phase difference signal PD. Hereinafter, the output of the OR gate 314 and the output of AND gate 315 are denoted by PD3 and PD4 respectively.

Incidentally, it is desirable that difference in the timing characteristics of F/Fs 306, 307, 308 and 309 and difference in the timing characteristics of the delay elements 310, 311, 312 and 313 are negligible respectively. In case that the difference in the timing characteristics is assumed to be negligible, since the output of F/F of which input clock is CLK3 and the output of F/F of which input clock is CLK4 are considered to change at the same timing, it is possible to reduce errors in the output of the phase difference detecting unit 300.

An operation of the phase difference detecting unit 300 according to the sixth exemplary embodiment will be described in the following. Relation between the values of PD3 and PD4 and the control operation for the delay circuit is shown in FIG. 10. In case that the phase of CLK3 is delayed in comparison with the phase of CLK4, PD3 and PD4 are set to zero together. In this case, an amount of delay time of the delay circuit 111 is set short so as to delay the phase of CLK4 and consequently, the phase of CLK 2 is delayed.

In case that the phase of CLK3 is advanced in comparison with that of CLK4, PD3 and PD4 are set to one together. In this case, an amount of delay time of the delay circuit 111 is set long reversely so as to advance the phase of CLK4 and consequently, the phase of CLK2 is advanced.

Through repeating the operation for adjusting the amount of delay time, it is possible to make the phases of CLK3 and CLK4 close each other. That is, the clock skew between CLK3 and CLK4 is reduced. As mentioned above, the function for reducing the clock skew by the phase adjustment for CLK2 is the same as that of the second exemplary embodiment.

The phase difference detecting unit 300 according to the sixth exemplary embodiment of the present invention has the function to detect whether the phases of CLK3 and CLK4 are identical each other, like the phase difference detecting unit 300 of the fifth exemplary embodiment. That is, since PD3 is set to zero and PD4 is set to one when the phases of CLK3 and CLK4 are identical each other, it is possible to detect that two phases are identical each other. In this case, the value of the delay time at the point of time is kept as the amount of the delay time of the delay circuit 111.

The problem, which is caused in case that the function to detect whether the phases of CLK3 and CLK4 are identical each other is not installed, and the reason why the problem can be settled by the clock distribution circuit of the sixth exemplary embodiment are the same as those described in the fifth exemplary embodiment.

As mentioned above, the phase detecting unit of the clock distribution circuit according to the sixth exemplary embodiment of the present invention has the function to detect whether the phases of clocks belonging to the two different clock systems are identical each other. Therefore, it is possible to prevent the clock skew due to the continuous phase adjustment. Therefore, the clock distribution circuit has an effect that it is possible to reduce clock skew more than the clock distribution circuit of the second and the third exemplary embodiments can reduce.

Moreover, there is no phenomenon that relation between CLK3 and CLK4 on the advance or the delay of the phase may be reversed every time. Therefore, the clock distribution circuit also has an effect that it is possible to prevent the problem of shortage in the timing margin of the logic circuit.

Incidentally, with reference to the description of the fifth and the sixth exemplary embodiments of the present invention, it is clear that various kinds of phase comparators are applicable to the phase difference detecting unit. Both a phase comparator which detects only the polarity of the phase difference like the phase difference detecting unit of the second to the fourth exemplary embodiments, and a comparator which detects the presence and the polarity of the phase difference like the phase difference detecting unit of the fifth and the sixth exemplary embodiments are applicable to the present invention.

The position of the delay circuit 111 is not limited to the position on the feed back clock line within the second clock output unit 102. As long as it is able to adjust the relative phase between CLK1 and CLK2, any position is admissible as the position of the delay circuit 111. The delay circuit 111 may be positioned, for example, on the input line for the reference clock CLK0 or the feedback line of PLL 113 included in the first clock output unit 101. Moreover, the delay circuit 111 may be positioned on the input line, which is for the reference clock CLK0, of PLL 112 included in the second clock output unit 102. Since the relative phase between CLK1 and CLK2 can be adjusted even if the delay circuit 111 is positioned at any place, the operation of the present invention can be achieved.

Incidentally, each of the above mentioned exemplary embodiments of the present invention can be combined with the other exemplary embodiment of the present invention. For example, it is possible to combine the function for short-circuiting the clocks according to the third and the fourth exemplary embodiments of the present invention, with the added function to the phase difference detecting unit according to the fifth and the sixth exemplary embodiments of the present invention.

According to the clock distribution circuit disclosed in the patent document 1, the phase of the reference clock supplied to PLL and the phase of the clock distributed from the predetermined branch point of the clock tree are aligned together by PLL. However, the wiring for inputting the reference clock to each PLL generates the delay time for transferring the clock. Therefore, the reference clock at the input point of each PLL has the clock skew. Accordingly, the clock distribution circuit disclosed in the patent document 1 causes a problem that the clock skew between the clock trees cannot be reduced sufficiently, even if the phase of the clock in each clock tree is aligned with the phase of the reference clock for each PLL.

Moreover, the clock, which is inputted to PLL as a clock of which phase is compared with the phase of the reference clock, is fed back from the predetermined branch point of the clock tree. However, the clock line from PLL to the branch point of the clock tree and the feedback clock line generate the transmission delay time. Moreover, the transmission delay time is not constant due to the variation in manufacturing process such as the semiconductor process. Meanwhile, the clock jitter is generated due to the noise by operation of the circuits, the variation of the rise time or the fall time, or the like. Therefore, the large clock skew exists also between the clocks each of which is fed back to respective PLL. Accordingly, the clock distribution circuit disclosed in the patent document 1 has also the problem that the outputs of PLLs have the clock skew.

The clock supplying device disclosed in the patent document 2 has the same problem as the clock distribution circuit disclosed in the patent document 1 has. That is, the clock skew is generated between the reference clocks inputted to PLLs and between the clocks inputted to the other clock system in order to adjust the phase. Therefore, the clock supplying device causes the problem that the skew between two clocks belonging to the two different clock systems each other can not be reduced sufficiently.

According to the present invention, the clock distribution device and the clock distribution method have an effect, for example, that it is possible to reduce the clock skew between the clocks belonging to a plurality of clock systems.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

Further, it is the inventor's intention to retain all equivalents of the claimed invention even if the claims are amended during prosecution.

1. A clock distribution device comprising:
a first clock output unit outputting a first clock synchronized to a reference clock;
a second clock output unit outputting a second clock synchronized to the reference clock;
a first clock distribution unit including a first branch point, branching the first clock at the first branch point and outputting a third clock;
a second clock distribution unit including a second branch point, branching the second clock at the second branch point and outputting a fourth clock; and
a phase difference detecting unit detecting a first phase difference between a phase of the third clock and a phase of the fourth clock, wherein
the second clock output unit controls a second phase difference between a phase of the first clock and a phase of the second clock so that the first phase difference is reduced.

2. The clock distribution device according to claim 1, wherein
the second clock output unit comprises:
a first delay circuit delaying the second clock by a first delay time based on the first phase difference and outputting the delayed second clock as a first feedback clock; and
a phase synchronization circuit outputting the second clock synchronized to the reference clock by controlling a third phase difference between a phase of the reference clock and a phase of the first feedback clock.

3. The clock distribution device according to claim 2, wherein
the first delay circuit increases or reduces the first delay time in a step of a time shorter than a predetermined acceptable phase difference of the first phase difference.

4. The clock distribution device according to claim 2, wherein
the phase difference detecting unit detects an advanced state in which the phase of the third clock leads the phase of the fourth clock or a delayed state in which the phase of the third clock follows the phase of the fourth clock, based on the first phase difference, and
the second clock output unit increases the first delay time in the advanced state and reduces the delay time in the delayed state.

5. The clock distribution device according to claim 4, further comprising:
a clock stop unit stopping an input of the third clock and the fourth clock to a first circuit except the phase difference detecting unit, in the advanced state or the delayed state.

6. The clock distribution device according to claim 2, wherein
the phase difference detecting unit detects an in-phase state in which the phase of the third clock equals the phase of the fourth clock, based on the first phase difference, and
the second clock output unit keeps the first delay time in the in-phase state.

7. The clock distribution device according to claim 2, further comprising:
a clock shorting unit shorting the third clock inputted to a second circuit except the phase difference detecting unit to the fourth clock inputted to the second circuit, in an in-phase state in which the phase of the third clock equals the phase of the fourth clock, wherein
the phase difference detecting unit detects the in-phase state based on the first phase difference.

8. The clock distribution device according to claim 1, wherein
the second clock output unit measures the first phase difference and sets the second phase difference based on the measured first phase difference.

9. The clock distribution device according to claim 1, wherein
the second clock output unit comprises:
a second delay circuit delaying the reference clock by a second delay time based on the first phase difference and outputting the delayed reference clock as a delayed reference clock; and
a second phase synchronization circuit outputting the second clock synchronized to the reference clock by controlling a fourth phase difference between a phase of the delayed reference clock and the phase of the second clock.

10. The clock distribution device according to claim 1, wherein
the first clock output unit comprises a third phase synchronization circuit feed-backing the first clock as a second feedback clock to an input of the first clock output unit and outputting the first clock synchronized to the reference clock by controlling a fifth phase difference between a phase of the reference clock and a phase of the second feedback clock.

11. A clock distribution device comprising:
a first clock output means for outputting a first clock synchronized to a reference clock;
a second clock output means for outputting a second clock synchronized to the reference clock;
a first clock distribution means for including a first branch point, branching the first clock at the first branch point and outputting a third clock;
a second clock distribution means for including a second branch point, branching the second clock at the second branch point and outputting a fourth clock; and
a phase difference detecting means for detecting a first phase difference between a phase of the third clock and a phase of the fourth clock, wherein
the second clock output means controls a second phase difference between a phase of the first clock and a phase of the second clock so that the first phase difference is reduced.

12. A clock distribution method comprising:
detecting a first phase difference between a phase of a third clock branched from a first branch point of a first clock distribution unit and a phase of a fourth clock branched from a second branch point of a second clock distribution unit; and
controlling a second phase difference between a phase of the first clock and a phase of the second clock so that the first phase difference is reduced.
